(19) United States
(12) Patent Application Publication
(10) Pub. No.: US 2019/0352764 A1
(43) Pub. Date: Nov. 21, 2019

(54) VAPOR DEPOSITION MASK AND MANUFACTURING METHOD FOR VAPOR DEPOSITION MASK

(71) Applicant: Sharp Kabushiki Kaisha, Sakai City, Osaka (JP)

(72) Inventor: Shinsaku NAKAJIMA, Sakai City (JP)

(21) Appl. No.: 16/469,168

(22) PCT Filed: Aug. 7, 2017
(86) PCT No.: PCT/JP2017/028592

§ 371 Date: Jun. 13, 2019

(51) Int. Cl. C23C 14/04; C23C 14/24; H01L 51/56

(52) U.S. Cl. CPC C23C 14/042; H01L 51/56; C23C 14/24

(57) ABSTRACT

In an opening in a mask frame, cover sheets intersect with support sheets by passing through recessed portions provided in the support sheets.

### TECHNICAL FIELD

The disclosure relates to a vapor deposition mask and a manufacturing method for a vapor deposition mask.

### BACKGROUND ART

Various types of flat panel displays are being developed in recent years. With their ability to achieve reduced power consumption, thinner profiles, and higher picture quality, Electroluminescence (EL) display devices in particular are attracting attention as excellent flat panel displays.

Examples of such EL display devices include organic Electro Luminescence (EL) displays equipped with Organic Light Emitting Diodes (OLEDs), EL displays such as inorganic EL displays provided with inorganic light emitting diodes, and Quantum Dot Light Emitting Diode (QLED) displays equipped with QLEDs.

When such EL display devices are manufactured, a vapor deposition film containing a high-resolution light-emitting layer is formed upon a substrate. High-resolution vapor deposition masks are therefore required, which has led to high demand for high-resolution vapor deposition masks.

PTL 1 discloses a vapor deposition mask including a frame-shaped mask frame having a large opening in its center, and unit mask members (also called “divided masks”). Each unit mask member has a plurality of unit masking pattern parts, and is elongated with respect to one direction in which the unit mask members overlap with each other by a prescribed width. The unit mask members, which are elongated with respect to the one direction, are fixed to the mask frame with tension applied in the one direction.

PTL 2 discloses a vapor deposition mask having a configuration in which unit mask members, each including a plurality of openings corresponding to a film pattern, are positioned relative to, and attached to, a single support substrate including a plurality of substrate-side openings constituted by rectangular through-holes.

### CITATION LIST

### Patent Literature

PTL 1: JP 2004-14513 A (published Jan. 15, 2004)

PTL 2: JP 2008-156686 A (published Jul. 10, 2008)

### SUMMARY

### Technical Problem

The vapor deposition mask disclosed in PTL 1 has a configuration including a plurality of unit mask members that are elongated in one direction, and the individual unit mask members easily bend in the longitudinal direction.

However, the vapor deposition mask disclosed in PTL 1 does not include a support sheet fixed to the frame-shaped mask frame and arranged in a direction orthogonal to the longitudinal direction for preventing the unit mask members from bending.

As such, with the vapor deposition mask disclosed in PTL 1, the effects of the unit mask members bending in the longitudinal direction result in a vapor deposition mask that does not have a fully satisfactory level of resolution.

On the other hand, with the vapor deposition mask disclosed in PTL 2, the individual unit mask members are short, and thus a problem like in the vapor deposition mask disclosed in PTL 1, where the unit mask members bend in the longitudinal direction, does not arise.

However, because the individual unit mask members are positioned relative to, and attached to, a single support substrate including a plurality of substrate-side openings constituted by rectangular through-holes, there is a problem in that the process for positioning and attaching the members is complex.

To ameliorate the problems with the vapor deposition masks disclosed in PTL 1 and PTL 2, a mask frame 102 including support sheets 103 and cover sheets 104 has been proposed, as illustrated in FIGS. 6A and 6B, described below.

FIG. 6A is a diagram illustrating the overall configuration of a known mask frame 102 to which the support sheets 103 and the cover sheets 104 are fixed, and FIG. 6B is an enlarged view of part C indicated in FIG. 6A.

The known mask frame 102 illustrated in FIG. 6A includes the support sheets 103, which are longer in a second direction, which is orthogonal to a first direction, than in the first direction, and which have a longitudinal direction following the second direction so as to prevent the elongated unit mask members (this is not illustrated, see FIG. 1) from bending. As such, the problem of the unit mask members bending in the longitudinal direction, which occurs in the vapor deposition mask disclosed in PTL 1, can be suppressed.

Additionally, in the known mask frame 102 illustrated in FIG. 6A, the individual elongated unit mask members (this is not illustrated, see FIG. 1) are fixed to the mask frame 102 with tension applied with respect to the first direction, with the cover sheets 104, which are disposed so that the longitudinal direction of the cover sheets 104 follows the first direction, are interposed between the unit mask members. This increases the efficiency of the positioning and attachment processes, and makes it possible to suppress a situation where the positioning and attachment processes become complex, as with the vapor deposition mask disclosed in PTL 2.

However, as illustrated in FIGS. 6A and 6B, the support sheets 103, which are disposed so that the longitudinal direction thereof follows the second direction, and the cover sheets 104, which are disposed so that the longitudinal direction thereof follows the first direction, are provided so as to intersect with each other at openings 102a in the mask frame 102. In a case where the cover sheets 104 pass above the support sheets 103 as illustrated in FIG. 6B, a step equivalent to the thickness of the cover sheets 104 is produced between the support sheets 103 and the cover sheets 104.

On the other hand, although not illustrated, in a case where the support sheets 103 pass above the cover sheets 104, a step equivalent to the thickness of the support sheets 103 is produced between the support sheets 103 and the cover sheets 104.

In a case where the step between the support sheets 103 and the cover sheets 104 is large, the unit mask members formed so as to contact the support sheets 103 will be unable to overlap with the cover sheets 104 in plan view due to the effects of the step equivalent to the thickness of the cover sheets 104, or will be formed separated from the cover sheets 104 due to the effects of the step equivalent to the thickness of the support sheets 103. This results in a problem in that the light-blocking effect of the cover sheets 104 will be weakened.

Having been achieved in light of the foregoing problems, an object of the disclosure is to provide a high-resolution vapor deposition mask that has a strong light-blocking effect from a cover sheet, as well as a manufacturing method for a high-resolution vapor deposition mask that has a strong light-blocking effect from a cover sheet and that suppresses a situation in which a process for positioning and attaching a unit mask member (a divided mask) becomes complex.

### Solution to Problem

To solve the above-described problems, a vapor deposition mask according to the disclosure is a vapor deposition mask including: a frame-shaped mask frame having an opening; a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction; a plurality of cover sheets fixed to the mask frame with a longitudinal direction of the cover sheets following the first direction; and a plurality of support sheets fixed to the mask frame with a longitudinal direction of the support sheets following the second direction. The plurality of cover sheets and the plurality of support sheets intersect with each other in the opening in the mask frame. At parts where the cover sheets intersect with the support sheets, the cover sheets intersect with the support sheets by passing through recessed portions provided in the support sheets. Each of the plurality of unit mask members contacts parts of the plurality of support sheets aside from the recessed portions, and each of the plurality of unit mask members is provided in a region, within the opening in the mask frame that is defined by the plurality of cover sheets.

According to this configuration, a step between the support sheets and the cover sheets can be reduced, which makes it possible to realize a high-resolution vapor deposition mask that has a strong light-blocking effect from the cover sheets.

To solve the above-described problems, a manufacturing method for a vapor deposition mask according to the disclosure is a manufacturing method for a vapor deposition mask, the vapor deposition mask including: a frame-shaped mask frame having an opening; a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction; a plurality of cover sheets fixed to the mask frame with a longitudinal direction of the cover sheets following the first direction; and a plurality of support sheets fixed to the mask frame with a longitudinal direction of the support sheets following the second direction. The method includes: forming recessed portions in each of the plurality of support sheets; in the opening in the mask frame, intersecting the plurality of cover sheets with the plurality of support sheets by passing through the recessed portions provided in the support sheets and fixing the plurality of cover sheets and the plurality of support sheets to the mask frame; and arranging the plurality of unit mask members in regions within the opening in the mask frame, which are defined by the plurality of cover sheets, in contact with parts of the plurality of support sheets aside from the recessed portions and fixing the plurality of unit mask members to the mask frame.

According to the above-described method, a step between the support sheets and the cover sheets can be reduced. Furthermore, the unit mask members, each of which has a plurality of opening groups including a plurality of openings, and in which the length in the first direction is greater than the length in the second direction orthogonal to the first direction, are positioned and attached. This makes it possible to realize a manufacturing method for a high-resolution vapor deposition mask, in which a light-blocking effect of the cover sheets is strong, and in which a situation where the process for positioning and attaching the unit mask members (divided masks) becomes complex is suppressed.

### Advantageous Effects of Disclosure

According to an aspect of the disclosure, a high-resolution vapor deposition mask that has a strong light-blocking effect from a cover sheet, as well as a manufacturing method for a high-resolution vapor deposition mask that has a strong light-blocking effect from a cover sheet and that suppresses a situation in which a process for positioning and attaching a unit mask member (a divided mask) becomes complex, can be provided.

### BRIEF DESCRIPTION OF DRAWINGS

FIG. 1 is a diagram illustrating an overall configuration of a divided mask.

FIGS. 2A to 2D are diagrams illustrating an overall configuration of and a manufacturing process for a vapor deposition mask according to a first embodiment.

FIG. 3A is a diagram illustrating an overall configuration of and a manufacturing process for a support sheet included in the vapor deposition mask, illustrated in FIG. 2D; and FIG. 3B is a diagram illustrating a part where a cover sheet and the support sheet intersect with each other in the vapor deposition mask illustrated in FIG. 2D.

FIGS. 4A to 4D are diagrams illustrating an overall configuration of and a manufacturing process for a vapor deposition mask according to a second embodiment.

FIG. 5A is a diagram illustrating an overall configuration and a manufacturing process for a support sheet included in the vapor deposition mask, illustrated in FIG. 4D; and FIG. 5B is a diagram illustrating a part where a cover sheet and the support sheet intersect with each other in the vapor deposition mask illustrated in FIG. 4D.

FIGS. 6A and 6B are diagrams illustrating an overall configuration of a known mask frame including support sheets and cover sheets.

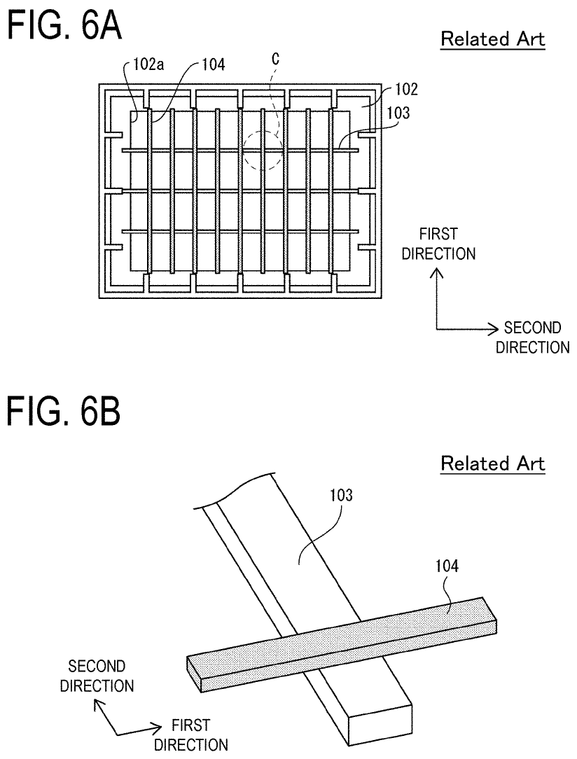

### DESCRIPTION OF EMBODIMENTS

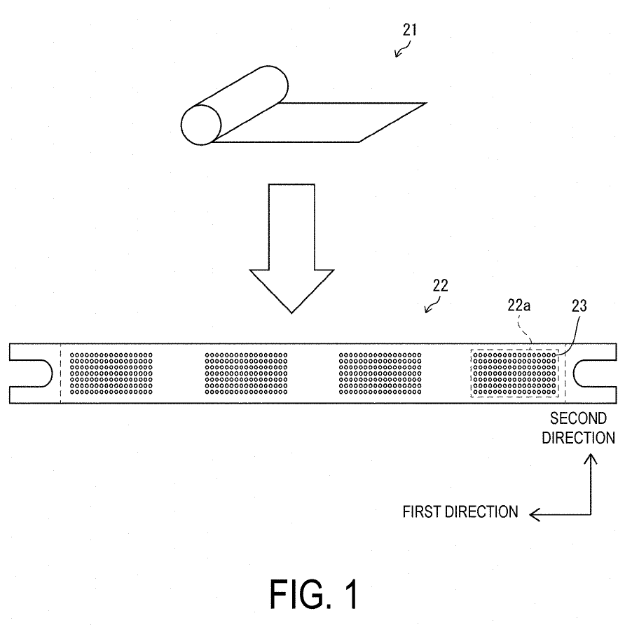

A description follows regarding embodiments of the disclosure, with reference to FIGS. 1 to 5B. Hereinafter, for convenience of descriptions, configurations having the same functions as those of configurations described in a specific embodiment are denoted by the same reference numerals, and its descriptions may be omitted.

The following embodiments describe a vapor deposition mask used when manufacturing an organic EL display device as an example. However, the disclosure is not limited thereto. For example, the vapor deposition mask may be a mask used when manufacturing an inorganic EL display, a QLED display, or the like.

### First Embodiment

A first embodiment of the disclosure will be described on the basis of FIGS. 1 to 3B.

FIG. 1 is a diagram illustrating the overall configuration of a divided mask (a unit mask member) 22.

As illustrated in FIG. 1, in the present embodiment, the divided mask 22 is obtained by subjecting a 30 μm-thick invar sheet material 21, which is in roll form, to an etching process for forming openings 23 and an attachment terminal portion, and a cutting process for obtaining individual units.

The thickness of the invar sheet material 21 is preferably greater than or equal to 10 μm and less than or equal to 50 μm, and is 30 μm in the present embodiment.

As illustrated in the drawing, the divided mask 22 includes a plurality of (four, in the present embodiment) opening groups 22a, each including the plurality of openings 23. The divided mask 22 has an elongated shape, in which the length of the mask in a first direction corresponding to the left-right direction in the drawing, is greater than the length in a second direction corresponding to the up-down direction in the drawing and is orthogonal to the first direction.

The present embodiment will describe a single opening group 22a as including openings for forming, for example, a red light-emitting layer of a single five-inch organic EL display device. However, the configuration is not limited thereto. It goes without saying that the size of a single opening group 22a, the number of openings 23 present in a single opening group 22a, and the like differ depending on the size, resolution, and the like of the organic EL display device being manufactured.

Furthermore, although the present embodiment describes a case where the divided mask 22 is formed using the invar sheet material 21 as an example, the configuration is not limited thereto. The divided mask 22 may be formed using a thin metal sheet, a thin alloy sheet, or the like instead of the invar sheet material 21.

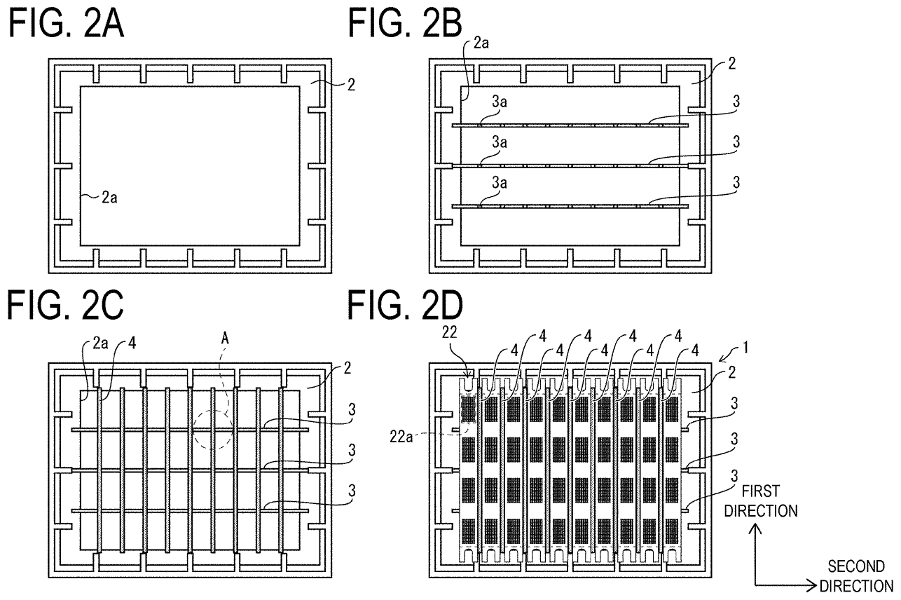

FIGS. 2A to 2D are diagrams illustrating an overall configuration of and a manufacturing process for a vapor deposition mask 1.

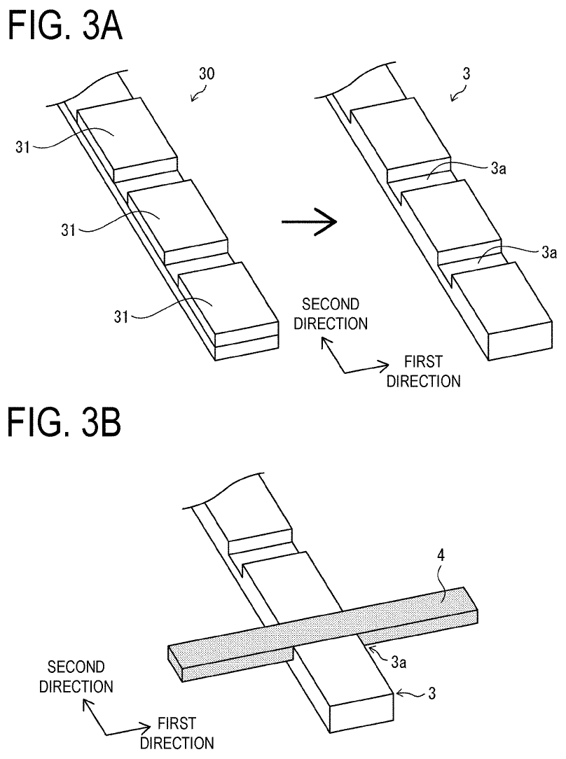

FIG. 3A is a diagram illustrating an overall configuration of and a manufacturing process for a support sheet 3 included in the vapor deposition mask 1, illustrated in FIG. 2D; and FIG. 3B is an enlarged view of a part indicated by a dotted line A in FIG. 2C.

The vapor deposition mask 1 includes: a mask frame 2; a plurality of the divided masks 22, which are fixed to the mask frame 2 at prescribed intervals; a plurality of the support sheets 3, which are fixed to the mask frame 2 so that the longitudinal direction of the support sheets 3 follows the second direction corresponding to the left-right direction in the drawing; and a plurality of cover sheets 4, which are fixed to the mask frame 2 so that the longitudinal direction of the cover sheets 4 follows the first direction corresponding to the up-down direction in the drawing.

FIG. 2A is a diagram illustrating an overall configuration of the frame-shaped mask frame 2 having an opening 2a.

As illustrated in FIG. 2B, the plurality of support sheets 3 are fixed to the mask frame 2 so that the longitudinal direction of the support sheets 3 follows the second direction, which is the left-right direction in the drawing.

In the present embodiment, the support sheets 3 are fixed to the mask frame 2 by welding the support sheets 3 to the mask frame 2, but the configuration is not limited thereto.

As illustrated in FIG. 2B, in each of the support sheets 3, recessed portions 3a are formed following the first direction, and the recessed portions 3a are formed at prescribed intervals along the second direction.

As illustrated in FIG. 3A, in the process for forming the support sheet 3 including the plurality of recessed portions 3a, the support sheet 3 having the plurality of recessed portions 3a formed with a prescribed regularity can be formed by first forming a resist film 31 in a predetermined region of a support sheet 30, and then carrying out half-etching using the resist film 31 as a mask.

As illustrated in FIG. 2C, the plurality of cover sheets 4 is fixed to the mask frame 2 in the opening 2a of the mask frame 2 so that each of the cover sheets 4 intersects with the support sheets 3 by passing through the plurality of recessed portions 3a provided in each of the plurality of support sheets 3.

In the present embodiment, the cover sheets 4 are fixed to the mask frame 2 by welding the cover sheets 4 to the mask frame 2, but the configuration is not limited thereto.

FIG. 3B is an enlarged view of a part indicated by the dotted line A in FIG. 2C. At the part where the cover sheet 4 and the support sheet 3 intersect with each other, the cover sheet 4 is arranged so as to be embedded in the recessed portion 3a of the support sheet 3.

As described above, the recessed portions 3a are formed in the support sheets 3, and the cover sheets 4 are arranged so as to be embedded in the recessed portions 3a of the support sheets 3. This makes it possible to reduce a step between the support sheets 3 and the cover sheets 4.

The thickness of the support sheets 3 is preferably greater than or equal to 80 μm and less than or equal to 200 μm, and is 100 μm in the present embodiment.

The thickness of the cover sheets 4 is preferably greater than or equal to 10 μm and less than or equal to 50 μm, and is 30 μm in the present embodiment.

In the present embodiment, the depth of the recessed portions 3a in the support sheets 3 is set to 30 μm, which is the thickness of the cover sheets 4. This makes it possible to ensure that the surfaces of the support sheets 3 are flush with the surfaces of the cover sheets 4, thus eliminating the step between the support sheets 3 and the cover sheets 4, as illustrated in FIG. 3B.

Note that the support sheets 3 and the cover sheets 4 may be formed of the same material, or of different materials. For example, the sheets may be formed of thin invar sheets, or sheets aside from invar, such as thin metal sheets or thin alloy sheets.

As illustrated in FIG. 2D, the plurality of divided masks 22 are fixed to the mask frame 2 with each of the plurality of divided masks 22 being in contact with parts of the plurality of support sheets 3 aside from the recessed portions 3a. Each of the divided masks 22 is provided in a region, within the opening 2a in the mask frame 2, that is defined by the plurality of cover sheets 4.

According to the vapor deposition mask 1 illustrated in FIG. 2D, a step between the support sheets 3 and the cover sheets 4 can be eliminated, which makes it possible to realize a vapor deposition mask 1 that has a strong light-blocking effect from the cover sheets 4.

Additionally, the cover sheets 4 are supported by the recessed portions 3a of the support sheets 3, and thus the strength of the cover sheets 4 can be improved as well.

Additionally, the divided masks 22 can be welded at the parts thereof that make contact with parts of the plurality of support sheets 3 aside from the recessed portions 3a.

Furthermore, the divided masks 22 are arranged on the support sheets 3 and the cover sheets 4, which are formed with their surfaces flush. The cover sheets 4 therefore do not protrude between adjacent ones of the divided masks 22.

In the present embodiment, the divided masks 22 are fixed to the mask frame 2 by welding the divided masks 22 to the mask frame 2, but the configuration is not limited thereto.

As illustrated in FIG. 2D, the plurality of support sheets 3 of the vapor deposition mask 1, which are fixed to the mask frame 2 so that the longitudinal direction of the support sheets 3 follows the second direction corresponding to the left-right direction in the drawing, suppress bending of the divided masks 22 with respect to the first direction.

Additionally, the plurality of cover sheets 4 of the vapor deposition mask 1, which are fixed to the mask frame 2 so that the longitudinal direction of the cover sheets 4 follows the first direction corresponding to the up-down direction in the drawing, eliminate a gap between adjacent ones of the divided masks 22.

The present embodiment describes an example in which the support sheets 3 are fixed to the mask frame 2 first, the cover sheets 4 are fixed to the mask frame 2 next, and the divided masks 22 are fixed to the mask frame 2 last, as illustrated in FIGS. 2A to 2D. However, the order in which these elements are fixed is not particularly limited. For example, the divided masks 22 may be fixed to the mask frame 2 first, one of the support sheets 3 and the cover sheets 4 may be fixed to the mask frame 2 next, and the other of the support sheets 3 and the cover sheets 4 may be fixed to the mask frame 2 last.

Furthermore, although not illustrated in FIGS. 2A to 3B, the support sheets 3 and the cover sheets 4 may be fixed through welding or the like.

### Second Embodiment

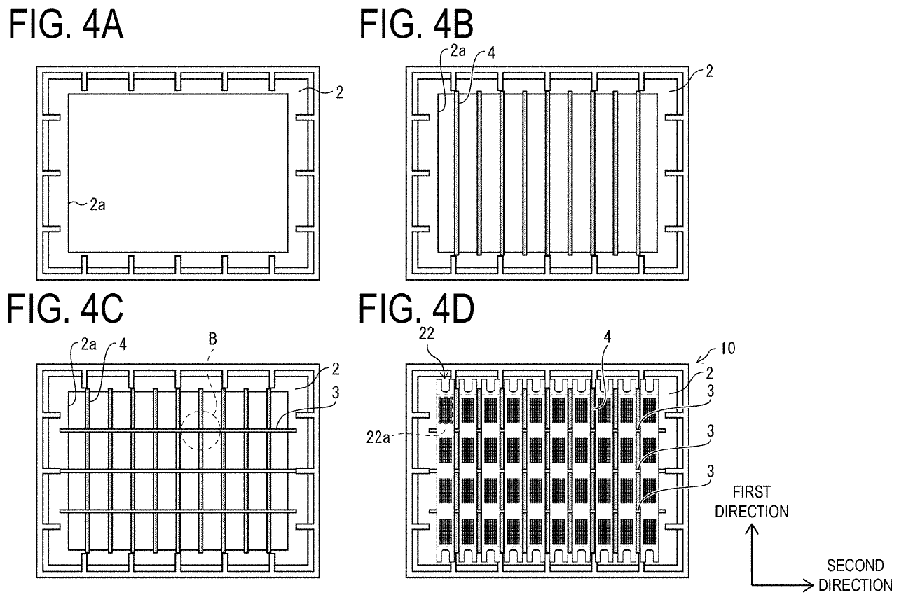

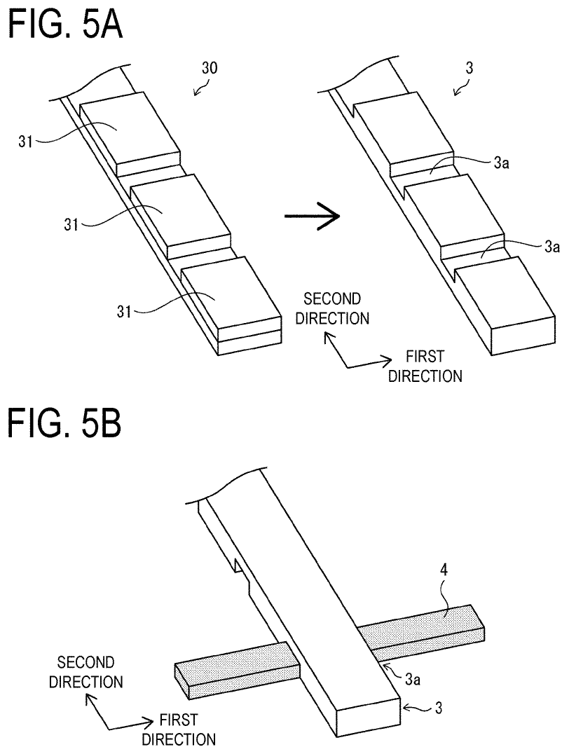

Next, a second embodiment of the disclosure will be described below with reference to FIGS. 4A to 5B. A vapor deposition mask 10 according to the present embodiment differs from the first embodiment in that at the parts where the support sheets 3 and the cover sheets 4 intersect with each other, the support sheets 3 are arranged so that the recessed portions 3a of the support sheets 3 cover the cover sheets 4. Aside from this, the configuration is the same as that described in the first embodiment. For convenience of descriptions, members having the same functions as those of the members illustrated in the diagrams in the first embodiment are denoted by the same reference numerals, and descriptions thereof will be omitted.

FIGS. 4A to 4D are diagrams illustrating the overall configuration and manufacturing process of the vapor deposition mask 10.

FIG. 5A is a diagram illustrating an overall configuration of and a manufacturing process for the support sheet 3 included in the vapor deposition mask 10, illustrated in FIG. 4D; and FIG. 5B is an enlarged view of a part indicated by a dotted line B in FIG. 4C.

The vapor deposition mask 10 includes: the mask frame 2; the plurality of divided masks 22, which are fixed to the mask frame 2 at prescribed intervals; the plurality of support sheets 3, which are fixed to the mask frame 2 so that the longitudinal direction of the support sheets 3 follows the second direction corresponding to the left-right direction in the drawing; and the plurality of cover sheets 4, which are fixed to the mask frame 2 so that the longitudinal direction of the cover sheets 4 follows the first direction corresponding to the up-down direction in the drawing.

FIG. 4A is a diagram illustrating an overall configuration of the frame-shaped mask frame 2 having the opening 2a.

As illustrated in FIG. 4B, the plurality of support sheets 3 are fixed to the mask frame 2 so that the longitudinal direction of the support sheets 3 follows the first direction corresponding to the up-down direction in the drawing.

As illustrated in FIGS. 4C and 5A, in each of the plurality of support sheets 3, the recessed portions 3a are formed following the first direction, and the recessed portions 3a are formed at prescribed intervals along the second direction.

In the opening 2a in the mask frame 2, at the parts where the cover sheets 4 and the support sheets 3 intersect with each other, the cover sheets 4 intersect with the support sheets 3 by passing through the recessed portions 3a provided in the support sheets 3.

Specifically, as illustrated in FIG. 5B, at the parts where the support sheets 3 and the cover sheets 4 intersect with each other, the support sheets 3 are arranged so that the recessed portions 3a of the support sheets 3 cover the cover sheets 4.

As described above, the recessed portions 3a are formed in the support sheets 3, and the support sheets 3 are arranged so that the recessed portions 3a of the support sheets 3 cover the cover sheets 4. This makes it possible to reduce a step between the support sheets 3 and the cover sheets 4.

According to the vapor deposition mask 10 illustrated in FIG. 4D, a step between the support sheets 3 and the cover sheets 4 can be reduced, which makes it possible to realize a vapor deposition mask 10 that has a strong light-blocking effect from the cover sheets 4.

Additionally, the support sheets 3 are supported by the cover sheets 4, and thus the strength of the support sheets 3 can be improved as well.

Additionally, the divided masks 22 can be welded at the parts thereof that make contact with the surfaces of the plurality of support sheets 3 on the sides opposite from the surfaces where the plurality of recessed portions 3a are formed.

### Supplement

To solve the above-described problems, a vapor deposition mask according to a first aspect of the disclosure is a vapor deposition mask including: a frame-shaped mask frame having an opening; a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction; a plurality of cover sheets fixed to the mask frame with a longitudinal direction of the cover sheets following the first direction; and a plurality of support sheets fixed to the mask frame with a longitudinal direction of the support sheets following the second direction. The plurality of cover sheets and the plurality of support sheets intersect with each other in the opening in the mask frame. At parts where the cover sheets intersect with the support sheets, the cover sheets intersect with the support sheets by passing through recessed portions provided in the support sheets. Each of the plurality of unit mask members contacts parts of the plurality of support sheets aside from the recessed portions, and each of the plurality of unit mask members is provided in a region, within the opening in the mask frame that is defined by the plurality of cover sheets.

According to this configuration, a step between the support sheets and the cover sheets can be reduced, which makes it possible to realize a high-resolution vapor deposition mask that has a strong light-blocking effect from the cover sheets.

According to a vapor deposition mask of a second aspect of the disclosure, preferably, in the first aspect, wherein the support sheets are formed thicker than the cover sheets; at the parts where the cover sheets and the support sheets intersect with each other, the cover sheets are embedded in the recessed portions of the support sheets; and a depth of the recessed portions in the support sheets is the same as the thickness of the cover sheets.

According to this configuration, a step between the support sheets and the cover sheets can be eliminated, which makes it possible to realize a vapor deposition mask that has a strong light-blocking effect from the cover sheets.

According to a vapor deposition mask of a third aspect of the disclosure, in the first aspect, at the parts where the cover sheets and the support sheets may intersect with each other, the cover sheets are covered by the recessed portions of the support sheets.

According to this configuration, a step between the support sheets and the cover sheets can be reduced, which makes it possible to realize a high-resolution vapor deposition mask that has a strong light-blocking effect from the cover sheets.

According to a vapor deposition mask of a fourth aspect of the disclosure, in any one of the first to third aspects, each of the plurality of unit mask members may be fixed to the plurality of support sheets.

According to this configuration, a vapor deposition mask with improved strength can be realized.

According to a vapor deposition mask of a fifth aspect of the disclosure, in any one of the first to fourth aspects, the plurality of unit mask members, the plurality of cover sheets, and the plurality of support sheets may be fixed to the mask frame through welding.

According to this configuration, a vapor deposition mask with improved strength can be realized.

According to a vapor deposition mask of a sixth aspect of the disclosure, in the fourth aspect, each of the plurality of unit mask members may be fixed to the plurality of support sheets through welding.

According to this configuration, a vapor deposition mask with improved strength can be realized.

According to a vapor deposition mask of a seventh aspect of the disclosure, in any one of the first to sixth aspects, the plurality of support sheets may be formed at a thickness of greater than or equal to 80 μm and less than or equal to 200 μm; the plurality of cover sheets may be formed at a thickness of greater than or equal to 10 μm and less than or equal to 50 μm; and the plurality of unit mask members may be formed at a thickness of greater than or equal to 10 μm and less than or equal to 50 μm.

According to this configuration, a vapor deposition mask in which parts aside from the mask frame are thin can be realized.

To solve the above-described problems, a manufacturing method for a vapor deposition mask according to an eighth aspect of the disclosure is a manufacturing method for a vapor deposition mask, the vapor deposition mask including: a frame-shaped mask frame having an opening; a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction; a plurality of cover sheets fixed to the mask frame with a longitudinal direction of the cover sheets following the first direction; and a plurality of support sheets fixed to the mask frame with a longitudinal direction of the support sheets following the second direction. The method includes: forming recessed portions in each of the plurality of support sheets; in the opening in the mask frame, intersecting the plurality of cover sheets with the plurality of support sheets by passing through the recessed portions provided in the support sheets and fixing the plurality of cover sheets and the plurality of support sheets to the mask frame; and arranging the plurality of unit mask members in regions within the opening in the mask frame, which are defined by the plurality of cover sheets, in contact with parts of the plurality of support sheets aside from the recessed portions and fixing the plurality of unit mask members to the mask frame.

According to the above-described method, a step between the support sheets and the cover sheets can be reduced. Furthermore, the unit mask members, each of which has a plurality of opening groups including a plurality of openings, and in which the length in the first direction is greater than the length in the second direction orthogonal to the first direction, are positioned and attached. This makes it possible to realize a manufacturing method for a high-resolution vapor deposition mask, in which a light-blocking effect of the cover sheets is strong, and in which a situation where the process for positioning and attaching the unit mask members (divided masks) becomes complex is suppressed.

According to a manufacturing method for a vapor deposition mask of a ninth aspect of the disclosure, in the eighth aspect, the support sheets may be formed thicker than the cover sheets; the forming the recessed portions in the plurality of support sheets includes forming the recessed portions to have a depth equal to a thickness of the cover sheets; and the fixing the plurality of cover sheets and the plurality of support sheets to the mask frame includes embedding the cover sheets in the recessed portions of the support sheets at parts where the cover sheets and the support sheets intersect each other.

According to this method, a step between the support sheets and the cover sheets can be eliminated, which makes it possible to realize a vapor deposition mask that has a strong light-blocking effect from the cover sheets.

According to a manufacturing method for a vapor deposition mask of a tenth aspect of the disclosure, in the eighth aspect, in the fixing of the plurality of cover sheets and the plurality of support sheets to the mask frame, the support sheets cover the cover sheets with the recessed portions of the support sheets at parts where the cover sheets and the support sheets intersect each other.

According to this method, a step between the support sheets and the cover sheets can be reduced, which makes it possible to realize a high-resolution vapor deposition mask that has a strong light-blocking effect from the cover sheets.

According to a manufacturing method for a vapor deposition mask of an eleventh aspect of the disclosure, in any one of the eighth to tenth aspects, the method may further include fixing each of the plurality of unit mask members to the plurality of support sheets.

According to this method, a vapor deposition mask with improved strength can be realized.

According to a manufacturing method for a vapor deposition mask of a twelfth aspect of the disclosure, in any one of the eighth to eleventh aspects, in the fixing of the plurality of cover sheets and the plurality of support sheets to the mask frame, and in the fixing of the plurality of unit mask members to the mask frame, the plurality of unit mask members, the plurality of cover sheets, and the plurality of support sheets may be welded to the mask frame.

According to this method, a vapor deposition mask with improved strength can be realized.

According to a manufacturing method for a vapor deposition mask of a thirteenth aspect of the disclosure, in the eleventh aspect, in the fixing of the plurality of unit mask members to the plurality of support sheets, the plurality of unit mask members may be welded to the plurality of support sheets.

According to this method, a vapor deposition mask with improved strength can be realized.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure can be applied in a vapor deposition mask and a manufacturing method for a vapor deposition mask.

### REFERENCE SIGNS LIST

1 Vapor deposition mask
2 Mask frame
2a Opening
3 Support sheet
3a Recessed portion
4 Cover sheet
10 Vapor deposition mask
21 Thin invar sheet
22 Divided mask (unit mask member)
22a Opening group
23 Opening

1. A vapor deposition mask comprising:
a frame-shaped mask frame having an opening;
a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction;
a plurality of cover sheets fixed to the mask frame with a longitudinal direction of the cover sheets following the first direction; and
a plurality of support sheets fixed to the mask frame with a longitudinal direction of the support sheets following the second direction,
wherein the plurality of cover sheets and the plurality of support sheets intersect with each other in the opening in the mask frame,
at parts where the cover sheets intersect with the support sheets, the cover sheets intersect with the support sheets by passing through recessed portions provided in the support sheets, and
each of the plurality of unit mask members contacts parts of the plurality of support sheets aside from the recessed portions, and each of the plurality of unit mask members is provided in a region, within the opening in the mask frame that is defined by the plurality of cover sheets.

2. The vapor deposition mask according to claim 1,
wherein the support sheets are formed thicker than the cover sheets,
at the parts where the cover sheets and the support sheets intersect with each other, the cover sheets are embedded in the recessed portions of the support sheets, and
a depth of the recessed portions in the support sheets is the same as the thickness of the cover sheets.

3. The vapor deposition mask according to claim 1,
wherein at the parts where the cover sheets and the support sheets intersect with each other, the cover sheets are covered by the recessed portions of the support sheets.

4. The vapor deposition mask according to claim 1,
wherein each of the plurality of unit mask members is fixed to the plurality of support sheets.

5. The vapor deposition mask according to claim 1,
wherein the plurality of unit mask members, the plurality of cover sheets, and the plurality of support sheets are fixed to the mask frame through welding.

6. The vapor deposition mask according to claim 4,
wherein each of the plurality of unit mask members is fixed to the plurality of support sheets through welding.

7. The vapor deposition mask according to claim 1,
wherein the plurality of support sheets are formed at a thickness of greater than or equal to 80 μm and less than or equal to 200 μm,
the plurality of cover sheets are formed at a thickness of greater than or equal to 10 μm and less than or equal to 50 μm, and
the plurality of unit mask members are formed at a thickness of greater than or equal to 10 μm and less than or equal to 50 μm.

8. A manufacturing method for a vapor deposition mask, the vapor deposition mask including:
a frame-shaped mask frame having an opening;
a plurality of unit mask members, the unit mask members being fixed to the mask frame at prescribed intervals, each of the plurality of unit mask members having a plurality of opening groups including a plurality of openings and having a length in a first direction being greater than a length of the unit mask member in a second direction orthogonal to the first direction;
a plurality of cover sheets fixed to the mask frame with a longitudinal direction of the cover sheets following the first direction; and
a plurality of support sheets fixed to the mask frame with a longitudinal direction of the support sheets following the second direction,
the method comprising:
forming recessed portions in each of the plurality of support sheets;
in the opening in the mask frame, intersecting the plurality of cover sheets with the plurality of support sheets by passing through the recessed portions provided in the support sheets and fixing the plurality of cover sheets and the plurality of support sheets to the mask frame; and
arranging the plurality of unit mask members in regions within the opening in the mask frame, which are defined by the plurality of cover sheets, in contact with parts of the plurality of support sheets aside from the recessed portions and fixing the plurality of unit mask members to the mask frame.

9. The manufacturing method for a vapor deposition mask according to claim 8,
wherein the support sheets are formed thicker than the cover sheets,
the forming the recessed portions in the plurality of support sheets includes forming the recessed portions to have a depth equal to a thickness of the cover sheets, and
the fixing the plurality of cover sheets and the plurality of support sheets to the mask frame includes embedding the cover sheets in the recessed portions of the support sheets at parts where the cover sheets and the support sheets intersect each other.

10. The manufacturing method for a vapor deposition mask according to claim 8,
wherein in the fixing the plurality of cover sheets and the plurality of support sheets to the mask frame, the support sheets cover the cover sheets with the recessed portions of the support sheets at parts where the cover sheets and the support sheets intersect each other.

11. The manufacturing method for a vapor deposition mask according to claim 8, further comprising:
fixing each of the plurality of unit mask members to the plurality of support sheets.

12. The manufacturing method for a vapor deposition mask according to claim 8,
wherein in the fixing of the plurality of cover sheets and the plurality of support sheets to the mask frame, and in the fixing of the plurality of unit mask members to the mask frame, the plurality of unit mask members, the plurality of cover sheets, and the plurality of support sheets are welded to the mask frame.

13. The manufacturing method for a vapor deposition mask according to claim 11,
wherein in the fixing of the plurality of unit mask members to the plurality of support sheets, the plurality of unit mask members are welded to the plurality of support sheets.
